(19) United States
(12) Patent Application Publication
(10) Pub. No.: US 2025/0040261 A1
(43) Pub. Date: Jan. 30, 2025

(54) WIRE BOND AND CIRCUIT BOARD INTERCONNECTS FOR SOLAR CELL MODULES

(71) Applicant: Maxeon Solar Pte. Ltd., Singapore (SG)

(72) Inventors: Chin Yeung WONG, Singapore (SG); Hui Khim CHO, Singapore (SG); Jeevan SIVARAMAN, Singapore (SG); Renante REFAMONTE, Singapore (SG)

(73) Assignee: Maxeon Solar Pte. Ltd., Singapore (SG)

(21) Appl. No.: 18/226,479

(22) Filed: Jul. 26, 2023

(51) Int. Cl. H01L 31/05; H01L 31/044; H01L 31/068; H01L 31/18

(52) U.S. Cl. CPC H01L 31/0516; H01L 31/044; H01L 31/068; H01L 31/18

(57) ABSTRACT

A solar cell module with interconnect wires wire-bonded to back-contact solar cells. A solar cell module using an interconnect board to electrical interconnect back-contact solar cells. The interconnect board may also contain a bypass diode and circuitry to connect the bypass diode to solar cells of the module.

### FIELD OF THE INVENTION

The invention relates generally to solar cell modules or panels and the solar cells within the solar cell modules.

### BACKGROUND

Alternate sources of energy are needed to satisfy ever increasing world-wide energy demands. Solar energy resources are sufficient in many geographical regions to satisfy such demands, in part, by provision of electric power generated with solar (e.g., photovoltaic) cells.

Generally, solar radiation impinging on the surface of, and entering into, the substrate of a solar cell creates electron and hole pairs in the bulk of the substrate. The electron and hole pairs migrate to p-doped and n-doped regions in the substrate, thereby creating a voltage differential between the doped regions. The doped regions are connected to conductive contacts on the solar cell to direct an electrical current from the cell to an external circuit. When solar cells are combined in an array such as a solar cell module, the electrical energy collected from all of the solar cells can be combined in series and parallel arrangements to provide power with a desired voltage and current.

### SUMMARY

This specification discloses a string of crystalline silicon solar cells. Each solar cell having a plurality of bond pads. The string of solar cells having a plurality of conductive interconnect wires. Each interconnect wire electrically connecting a first solar cell to an adjacent second solar cell in series. Each interconnect wire comprising a first wedge bond bonding the interconnect wire to a bond pad on the first solar cell and a second wedge bond bonding the interconnect wire to a bond pad on the second solar cell. Each interconnect wire may comprise multiple wedge bonds bonding the interconnect wire to bond pads on the first solar cell and multiple wedge bonds bonding the interconnect wire to bond pads on the second solar cell.

This specification discloses a method of making the string of crystalline silicon solar cells using wire bonding techniques. The method starts by placing a first and second crystalline silicon solar cells onto a fixture. Each solar cell has a plurality of bond pads. Next, placing a plurality of conductive interconnect wires on the first and second solar cell. Then, ultrasonic wire bonding each interconnect wire to a bond pad on the first solar cell and a bond pad on the second solar cell. The ultrasonic wire bonding forms wedge bonds.

The fixture upon which solar cells are placed may comprise areas configured to receive the solar cells and hump features between the areas. The humps features are configured to guide misplaced solar cells into the areas configured to receive the solar cells. Before ultrasonic wire bonding, placing clamps onto the hump features to clamp down on the interconnect wires thereby holding the wires in place. The clamps may be heated to mold the clamped wires to conform to the shape of the hump feature. This produces a bend in the interconnect wire located between the first and second solar cells of the string.

Each solar cell in the string and the method of making said string may be a back-contact solar cell with bond pads disposed on a rear (or back) surface of the solar cell. The bond pads of the solar cells may be coated with a tin alloy. The interconnect wire in the string of solar cells may comprise a copper core with a tin alloy coating. The tin alloy of the wire and the bond pads may be a solder material. The diameter of each interconnect wire may be greater than 200 μm.

This specification discloses interconnecting solar cells using an interconnect board. This specification discloses a solar module having an interconnect board. The interconnect board comprises a conductive layer sandwiched between two insulating layers. The conductive layer contains a conductive trace and bond pads. One of the two insulating layers has a plurality of openings. Each opening in the insulating layer is aligned with one of the bond pads of the conductive layer. The openings are filled with solder joints. The solar module has back-contact solar cells attached to the interconnect board. Each back-contact solar cell has one or more bond pads disposed on the back surface of the solar cell. The solar cells are attached to the interconnect board so that a solder joint is in contact with one of the bond pads of the interconnect board and one of the bond pads of an attached solar cell. The conductive trace of the interconnect board electrically connects the attached solar cells.

This specification discloses an interconnect board. The interconnect board comprises a conductive layer sandwiched between two insulating layers. The conductive layer contains a conductive trace and bond pads. One of the two insulating layers has a plurality of openings. Each opening in the insulating layer is aligned with one of the bond pads of the conductive layer. The interconnect board has a solder slug located within each opening. Each solder slug is in contact with a bond pad.

This specification discloses a method of manufacturing a solar module using the above-mentioned interconnect board. The method comprises placing back-contact solar cells unto the interconnect board so that the bond pads of the solar cells are in contact with the solder slugs of the interconnect board. Then, laminating the interconnect board and the attached solar cells in an encapsulant at a temperature sufficient to reflow solder the bond pads of the solar cells to the bond pads of the interconnect board.

This specification discloses a first alternate interconnect board. This interconnect board comprises a conductive layer sandwiched between two insulating layers. The conductive layer contains a conductive trace. The interconnect board has a plurality of openings passing through the interconnect board and a plurality of bond pads disposed on the surface of the interconnect board and adjacent to an opening. The interconnect board further comprises electrical paths, e.g. blind vias. Each electrical path connects a bond pad to the conductive trace.

This specification discloses a method of manufacturing a solar module using this first alternate interconnect board. The method starts with attaching a back-contact solar cell onto the surface of the interconnect board opposite from where the bond pads are disposed. Then, wire bonding a wire to a bond pad of the solar cell and to one of the bond pads of the interconnect board where the wire passes through one of the openings of the interconnect board. The method further comprises attaching a second solar cell to the interconnect board and wire bonding a second wire to the bond pad of the second solar cell and to another of the bond pads of the interconnect board. This second wire passes through one of the openings of the interconnect board.

The specification discloses a solar module containing the first alternate interconnect board. The solar module comprises back-contact solar cells attached to the first alternate interconnect board; a first wire wire-bonded to the bond pad on a first solar cell and wire-bonded to one of the bond pads of the interconnect board where the first wire passes through one of the openings; and a second wire wire-bonded to the bond pad on a second solar cell and wire-bonded to another of the bond pads of the interconnect board where the second wire passes through another of the openings. The conductive trace of the interconnect board electrically connects the first solar cell to the second solar cell.

This specification discloses a second alternative interconnect board. This interconnect board has a first surface and an oppositely positioned second surface. The interconnect board comprises a conductive layer sandwiched between two insulating layers. The conductive layer contains a conductive trace. The interconnect board has a plurality of bond pads disposed on the first surface of the interconnect board. Each bond pad has two parts: a first part and a second part. Each bond pad also has an electrical path, e.g. a blind via, connecting the bond pad to the conductive trace. The interconnect board has a plurality of reactive multilayer foils with each reactive multilayer foil disposed on a bond pad so that the foil is in contact with both parts of the bond pad. The interconnect board also has a first electrical path, e.g. a through via, contacting the first part of a bond pad and extending through the interconnect board to the second surface. The interconnect board has a second electrical path, e.g. a through via, contacting the second part of the bond pad and extending through the interconnect board to the second surface. In some instances, the reactive multilayer foil is made of alternating layers of aluminum and nickel. The reactive multilayer foil may have a thickness of less than 300 micrometers.

This specification discloses a method of interconnecting solar cells using the second alternate interconnect board. The method starts with placing back-contact solar cells onto the interconnect board so that the bond pads of the solar cell are aligned with and in contact with the reactive multilayer foils. Next is applying a voltage across the first and second parts of the bond pads of the interconnect board to activate the reactive multilayer foils to solder the bond pads of the solar cells to the bond pads of the interconnect board. After the bonds pads of the solar cells are soldered to the bond pads of the interconnect board, the conductive layer of the interconnect board will electrically interconnect the attached solar cells.

This specification discloses a solar module having the second alternate interconnect board. The solar module contains the second alternate interconnect board having a conductive layer comprising a conductive trace. The conductive layer sandwiched between two insulating layers. Bond pads are disposed on the surface of the interconnect board, and a plurality of electrical paths connect each bond pad to the conductive trace. Back contact solar cells are attached to the interconnect board such that the bond pads of the solar cells are soldered to the bond pads of the interconnect board. The solder attaching the bond pads contains a reaction product from the activation of a reactive multilayer foil. The conductive trace of the interconnect board electrically interconnects the attached solar cells.

The interconnect boards described above may have a thermal interface material. This thermal interface material may be a b-stage adhesive. The thermal interface material bonds the solar cells to the interconnect board. The thermal interface material may be tacky but not fully cured when the solar cells are placed upon the interconnect board and may be fully cured in a subsequent step.

The insulating layers of the above-described interconnect boards may comprise polyimide and a either FR-4, CEM1, CEM2, CEM3, or CEM4.

The above-described interconnect boards may have a second conductive layer. The second conductive layer is sandwiched between two insulating layers. For example, the interconnect board may comprise two conductive layers sandwiched between three insulating layers. The above-described interconnect boards may have electrical paths, e.g. vias, connecting the bond pads of the interconnect board with conductive traces in the second conductive layer. The above-described interconnect boards may have a bypass diode. When solar cells are attached to the interconnect board, the conductive traces in the second conductive layer connect each attached solar cells to the bypass diode.

### BRIEF DESCRIPTION OF THE DRAWINGS

The figures described below depict various aspects of the system and methods disclosed herein. Each figure depicts an embodiment of a particular aspect of the disclosed system and methods, and that each of the figures is intended to accord with a possible embodiment thereof. Further, wherever possible, the following description refers to the reference numerals included in the following figures, in which features depicted in multiple figures are designated with consistent reference numerals.

FIG. 1 shows a flowchart of a method of manufacturing a string of solar cells.

FIG. 2 shows the back side of a solar cell.

FIG. 3 shows solar cells placed in a fixture.

FIGS. 4A & 4B show steps for attaching interconnect wires to solar cells.

FIG. 5 shows the inner surface of a wire clamp.

FIG. 6 shows the step of wire bonding interconnect wires to a solar cell.

FIG. 7 shows the step of wire bonding the interconnect wires to another solar cell.

FIG. 8A shows wires interconnecting solar cells.

FIG. 8B shows a wedge bond bonding an interconnect wire to a solar cell.

FIG. 9 shows a cross sectional view of an interconnect board.

FIG. 10 shows a plan view of the interconnect board in FIG. 9.

FIG. 11 shows a cross sectional view of a solar module.

FIG. 12 shows a cross sectional view of an interconnect board.

FIG. 13 shows a plan view of the interconnect board in FIG. 12.

FIG. 14 shows a cross sectional view of the interconnect board of FIG. 12 with attached solar cells.

FIG. 15 shows a plan view of FIG. 14.

FIG. 16 shows a cross sectional view of an interconnect board with attached solar cells.

FIG. 17 is a schematic illustration of solar cells electrically connected to a bypass diode.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention.

As used in this specification and the appended claims, the singular forms “a,” “an,” and “the” include plural referents unless the context clearly indicates otherwise. Also, the term “parallel” is intended to mean “substantially parallel” and to encompass minor deviations from parallel geometries. The term “perpendicular” is intended to mean “perpendicular or substantially perpendicular” and to encompass minor deviations from perpendicular geometries rather than to require that any perpendicular arrangement described herein be exactly perpendicular. The term “square” is intended to mean “square or substantially square” and to encompass minor deviations from square shapes, for example substantially square shapes having chamfered (e.g., rounded or otherwise truncated) corners. The term “rectangular” is intended to mean “rectangular or substantially rectangular” and to encompass minor deviations from rectangular shapes, for example substantially rectangular shapes having chamfered (e.g., rounded or otherwise truncated) corners or may have non-linear edges. The term “identical” is intended to mean “identical or substantially identical” and to encompass minor deviations in shape, dimensions, structure, composition, or configuration, for example.

This specification discloses solar modules (also referred to as solar panels) comprising crystalline silicon solar cells electrically connected together using an interconnect. This specification discloses forming the interconnect using ultrasonic wire bonding techniques. This specification also discloses using a circuit board to form the interconnection between solar cells.

In the examples described in this specification, each solar cell is a crystalline silicon solar cell having front (sunny side) surface and rear or back (shaded side) surface. Between the front surface and rear surface are at least one doped semiconductor region of p-type conductivity and at least one doped semiconductor region of n-type conductivity. Certain crystalline-silicon solar cells can be based on a back-contact (or rear-contact) design, which seeks to minimize front-side metallization and to maximize working cell area. In such back-contact solar cells, the doped regions are coupled to conductive contacts or pads to form metal-semiconductor contacts. These contacts (some positive and some negative) are placed on the backside of the solar cell to allow external electrical circuits to be coupled and powered by the solar cell. One advantage of placing all the contacts of a solar cell on the backside is that it avoids placing metal contacts on the front side of the solar cell where the metal contacts will obscure part of the solar cell and reduce absorbed light in the solar cell.

Several solar cells can be connected together in series to form a solar cell string. In a solar cell string, a positive metal contact coupled to p-doped semiconductor of one solar cell is connected to a negative metal contact coupled to n-doped semiconductor of an adjacent solar cell. The p-doped region of one solar cell is thus connected to an n-doped area of an adjacent solar cell. Chaining of solar cells can be repeated to connect several solar cells in series, thereby increasing the output voltage of the solar module. Several solar cell strings may also be connected in parallel to increase current supplied by the solar module.

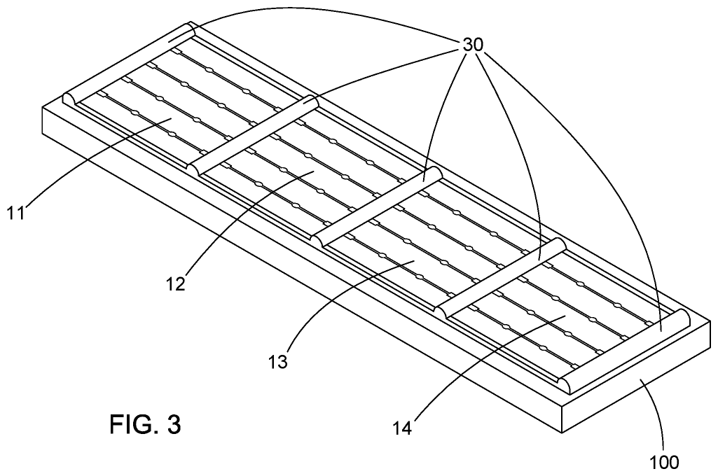

FIG. 2 shows a plan view of the rear or back side of a back-contact crystalline silicon solar cell. A plurality of alternating N-type and P-type metal-semiconductor contacts 21 and 22 are placed on the back side of solar cell 10. The number of metal contacts 21 and 22 may vary, but for a back-contact solar cell a minimum of 2 contacts (one n-type and one p-type) is required. Each metal contact may include one or more bond pads 25. These bond pads are regions of the metal contact or metallization having greater surface area to allow for connections to external circuitry.

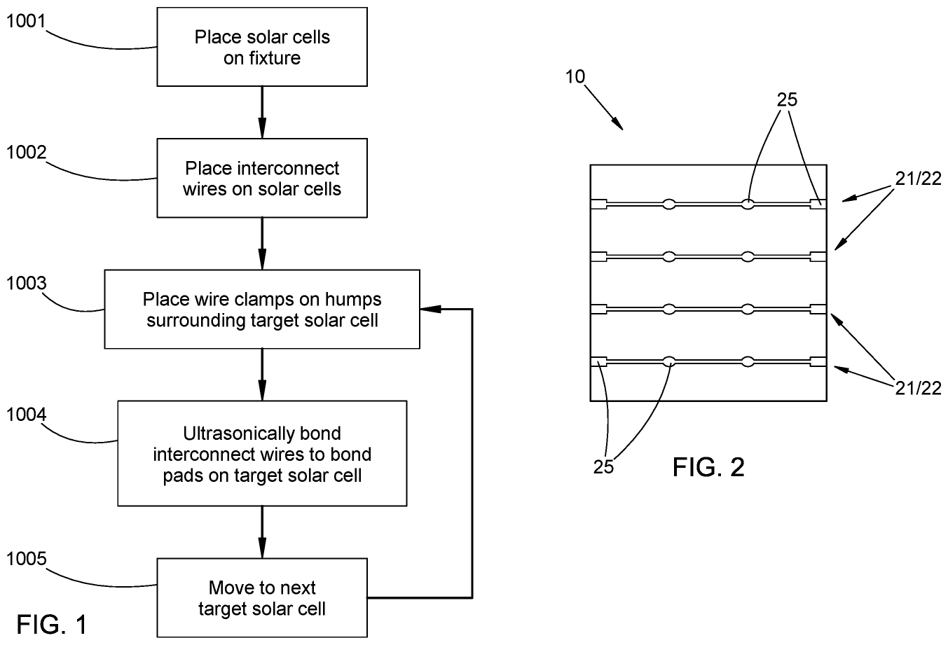

FIG. 1 shows a flow diagram of a process of using wire bonding to interconnect solar cells. Wire bonding is a process that uses a thin wire, ultrasonic energy, pressure and/or heat to create electrical interconnections. Wire bonding attaches a wire to a bond pad as the wire is held in close contact with the bond pad. The wire bonding process does not use additional solder to bond the wire to the bond pad. Two types of bonds may be formed using wire bonding: a wedge bond and a ball bond. As used herein, the term “wire bond” includes either a wedge bond or a ball bond.

In step 1001, solar cells are placed on a belt jig fixture. FIG. 3 illustrates four back-contact solar cells 11, 12, 13, and 14 placed on fixture 100. The solar cells are placed in the fixture with the backsides of the solar cells facing up. The solar cells may be held to fixture 100 by vacuum created through vacuum inlets underneath the solar cells (not shown). Fixture 100 has humps 30 used for guiding solar cell placement onto fixture 100 and for wire guidance. The humps may have a semi-circular cross-sectional area. The top surface of the hump slopes downwards towards the area on the fixture the solar cells should be placed. If a solar cell is slightly misplaced on the fixture, the downward slope of the hump helps guide the solar cell into correct placement.

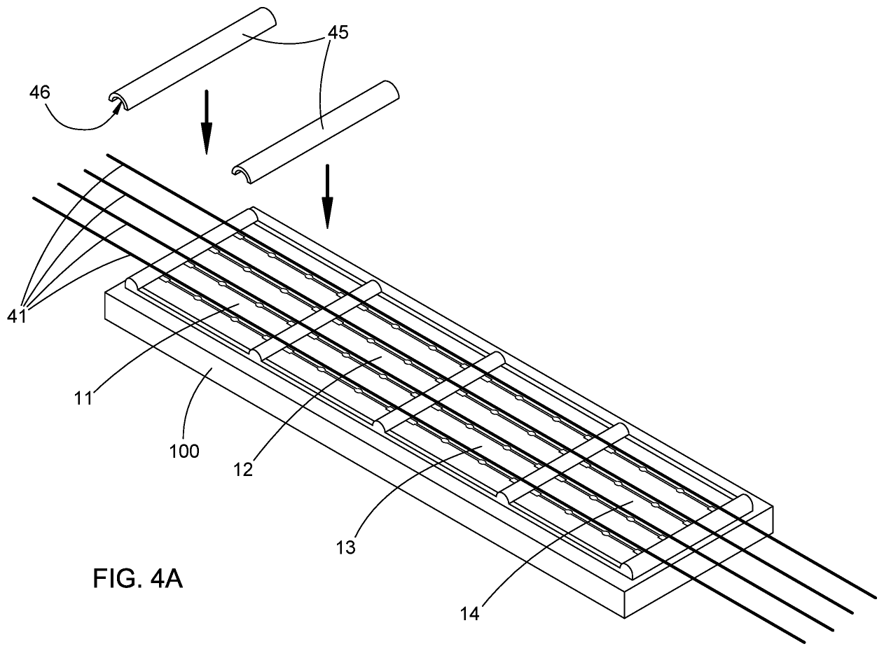

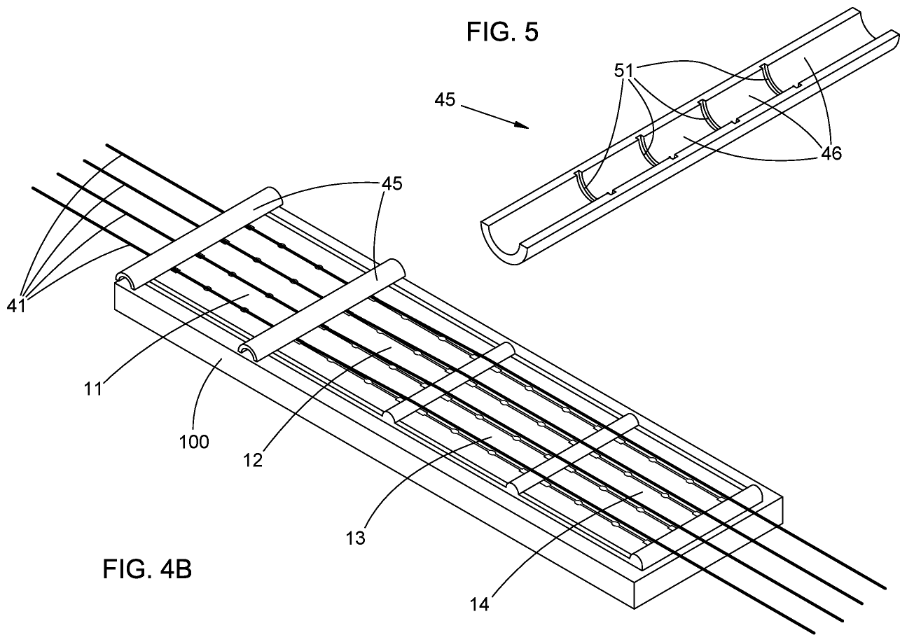

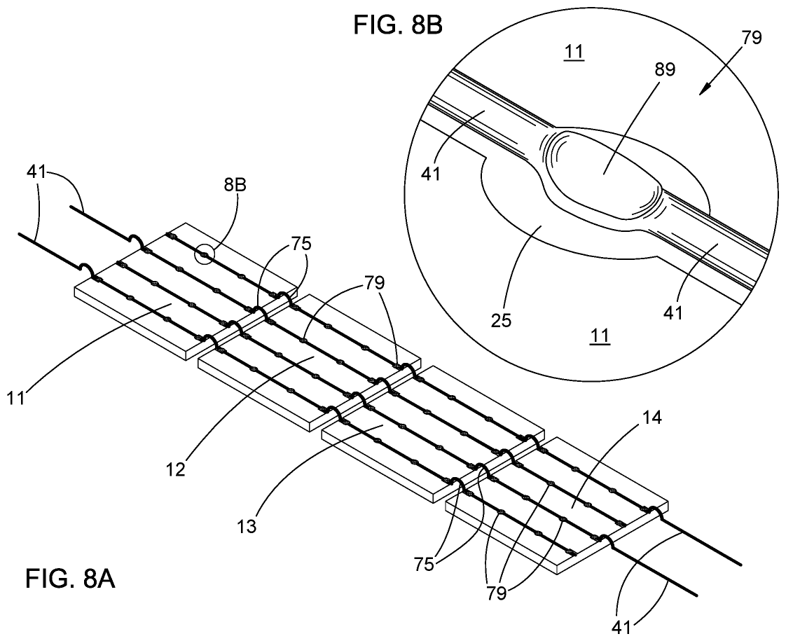

In step 1002 of FIG. 1, interconnect wires are placed on the solar cells. FIG. 4A shows wires 41 placed onto solar cells 11, 12, 13, and 14. The wires are placed above and in alignment with the bond pads of the solar cells. In step 1003 of FIG. 1, wire clamps are placed on the humps surrounding the target solar cell. In FIG. 4A, the target solar cell is solar cell 11. Two wire clamps 45 are placed the humps flanking solar cell 11 as shown in FIG. 4B. Wire clamps have an inner surface 46 that conforms with the top surface of the humps. For example, if the humps have a semi-circular cross-sectional area, then the inner surface of the wire clamps will also have a semi-circular cross section. The inner surface of the wire clamp includes wire guides 51 as shown in FIG. 5. Wire guides are slots on the inner surface of the wire clamp. When a wire clamp is placed on the fixture hump, the interconnect wires fit within the slots. The slots in the wire clamps hold interconnect wire in the correct position, i.e. aligned with the bond pads of the target solar cell. The wire clamps may be heated which heats the interconnect wire held under the wire clamps. The heat from the wire clamps molds the wires to conform with the shape of the underlying hump. This will create a bend in the interconnect wire between two adjacent solar cells in a solar cell string as shown in FIG. 8.

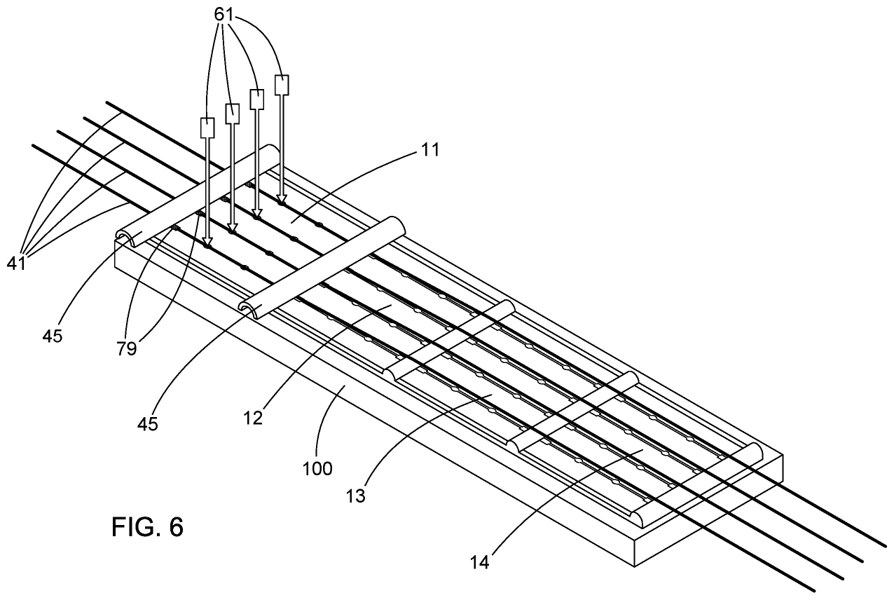

In step 1004 of FIG. 1, the interconnect wire is bonded to the bond pads of the target solar cell by ultrasonic wire bonding. FIG. 6 schematically illustrates ultrasonic wedge head 61 pressing against interconnect wire 41 which presses the wire into the underlying bond pad of the solar cell. While pressing, wedge head 61 applies ultrasonic energy to the wire using a low frequency transducer operating between 50-80 khz for between 110-130 milliseconds to create a wedge bond. This wire bonding process is carried out at ambient temperature without additional heat input. Inventors have discovered that coated copper core wires with a diameter 200 μm or greater work well for this interconnect wire bonding process. Interconnect wires should be able to carry a current load of up to 10 A. A wire with a copper core diameter 200 μm or greater is well suited for carrying a current load of up to 10 A while a coating can be adapted to make a more secure bond with the bond pad. The interconnect wire may have an aluminum shell over a copper core. The interconnect wire may have a tin alloy coating, for example, a tin-bismuth coating, over a copper core. The interconnect wire may have a low melt-point, lead-free, solder alloy coating over a copper core. Inventors have discovered that the tin alloy or solder alloy coating of the interconnect wire bonds well with tin alloy coated bond pads of a solar cell.

For higher bonding throughput, multiple bond heads may be used simultaneously. FIG. 6 shows 4 ultrasonic wedge heads 61 being used simultaneously. A greater number of heads may be used simultaneously for even greater bonding throughput.

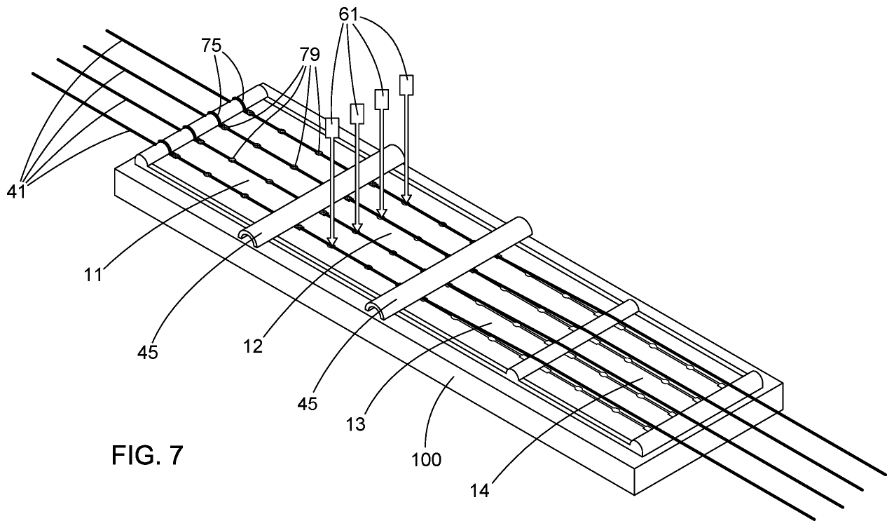

In step 1005 of FIG. 1, the wire clamps are released and the ultrasonic wedge heads 61 are moved to the next target solar cell. This may be accomplished by either moving the ultrasonic wedge heads or by keeping the wedge heads stationary and moving the fixture and target solar cell. FIG. 7 shows ultrasonic wedge heads 61 bonding interconnect wires 41 to target solar cell 12. The process repeats for the new target cell by proceeding back to step 1003, i.e. placing the wire clamps on the humps surrounding the target solar cell, etc. The loop of steps 1003, 1004, and 1005 repeats until no further solar cell needs to be added to the solar cell string.

FIG. 7 shows wire clamps 45 placed on the humps surrounding solar cell 12 and ultrasonic wedge heads 61 wire bonding interconnect wires 41 to solar cell 12. FIG. 7 also shows the results of proceeding through steps 1003, 1004, and 1005 on previous target solar cell 11. Interconnect wire 41 includes bend 75 made by the heated wire clamps. Interconnect wire 41 also has wedge bond 79 created by wire bonding. Generally, each interconnect wire may have one or more wedge bonds 79 bonding the interconnect wire to a solar cell.

FIG. 8A shows a string of 4 back-contact solar cells after the string has been removed from the fixture. More or less than 4 solar cells may be in a string depending on the requirements of the solar module design. The string shown in FIG. 8A contains 4 interconnect wires. The interconnect wires may be cut at different locations according to the design specifications. More or less than 4 interconnect wires may be used depending on design requirements. The interconnect wires have bends 75 located between adjacent solar cells. The bends in the interconnect wire provide strain relief for the wire. For example, the solar cells in the string may move apart due to thermal expansion of the solar module. The bends in the interconnect wire allow the wire to unfold during thermal expansion rather than break under tension. Interconnect wire 41 is bonded to solar cell 11 by one or more wedge bonds 79 which were created using ultrasonic wedge head 61. FIG. 8B shows a schematic close-up view of wedge bond 79 in interconnect wire 41. The region 89 is where the ultrasonic wedge head pressed against the interconnect wire creating a flattened area in the interconnect wire and a bond between interconnect wire 41 and bond pad 25 of the solar cell.

Ultrasonic wire bonding has several advantages over soldering. Because ultrasonic wire bonding does not use additional solder for the bonding process, bond placement may be more finely calibrated since the width of the bond is essentially the width of the wire. With soldering, additional solder is used for the bonding process and so the width of the bond depends on how the solder is formed. Therefore, in addition to accurate wire placement, the additional solder must also be accurately placed. Large variability in solder placement and soldering experience results in electrical shorting of the solar cell metallization when the solder is misplaced. Ultrasonic wire bonding may provide higher throughput in solar module manufacturing since a wedge bond may be formed in as little as 130 milliseconds. Ultrasonic wire bonding may provide higher throughput and cost saving due to the elimination of solder and solder handling steps in the manufacturing process.

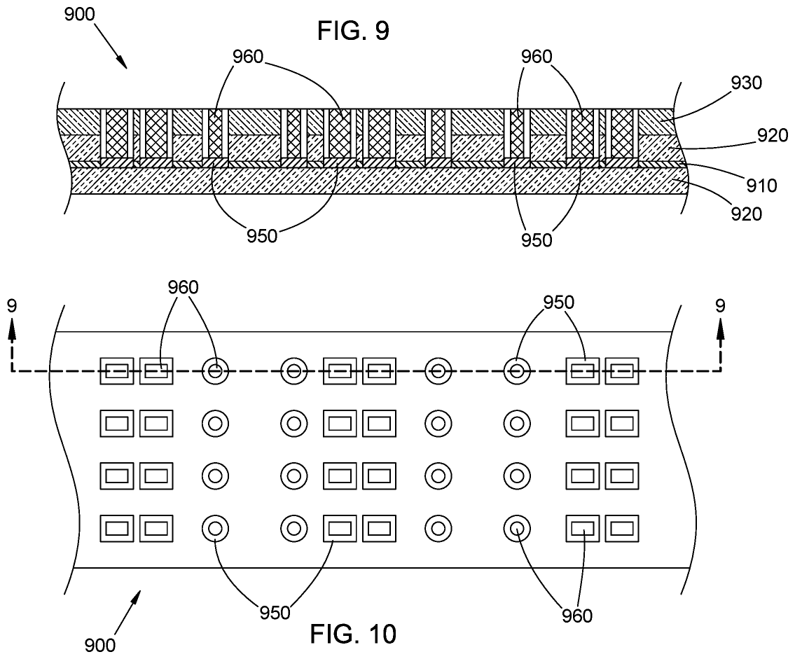

In addition to wire bonding, solar cells may be interconnected using an interconnect board. FIG. 10 shows a plan view of interconnect board 900. FIG. 9 shows a cross sectional view of interconnect board 900 taken from line 9-9 in FIG. 10. Interconnect board 900 is configured to electrically connect adjacent solar cells attached to the interconnect board. Interconnect board 900 comprises a conductive layer 910 sandwiched between two insulating layers 920. Conductive layer 910 may be made from copper and may be etched to form conductive traces. The insulating layers may comprise FR-4, polyimide, CEM-1, CEM-2, CEM-3, or a combination of these materials. A combination of FR-4 and polyimide may provide a desired combination of flexibility and cost effectiveness. A combination of CEM-1 and polyimide may provide a desired combination of flexibility, cost effectiveness, and heat dissipation. A thermal interface material 930 is disposed on top of one of the insulating layers. Thermal interface material 930 enhances the heat dissipation of an attached solar cell. The thermal interface material may also be a b-stage thermal adhesive.

Interconnect board 900 includes bond pads 950 electrically connected to conductive traces in conductive layer 910. The bond pads of the interconnect board are arranged to match the bond pad arrangement on the solar cell to be attached. The arrangement of bond pads in the interconnect board is shown in FIG. 10. The one of the insulating layers covers the edges of the bond pads creating solder mask defined pads. Disposed on top of each bond pad 950 is a solder slug 960.

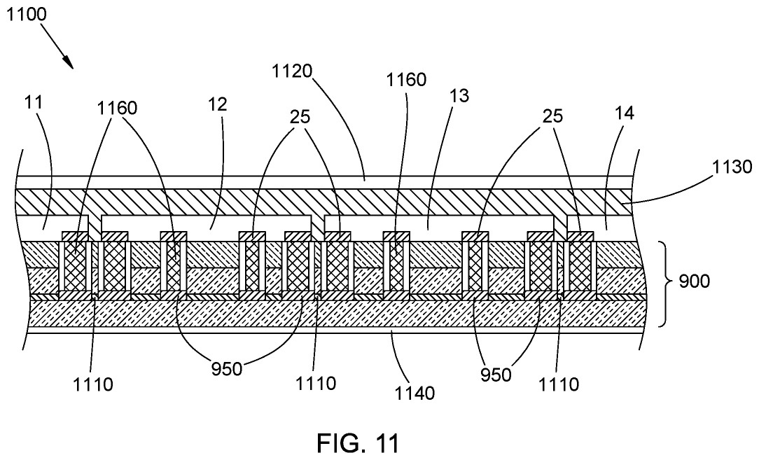

To form a solar module, solar cells are placed on the thermal interface material of the interconnect board so that bond pads 25 of the solar cell are in contact with a solder slug 960 and aligned with bond pads 950 of the interconnect board. The interconnect board and solar cells are then laminated together with encapsulant, an optional back sheet, and a transparent front sheet made from glass or clear encapsulant or other material. The structure after lamination is shown in FIG. 11 includes solar cells 11, 12, 13 and 14; interconnect board 900; transparent front sheet 1120; encapsulant 1130; and back sheet 1140.

FIG. 11 shows interconnect board 900 interconnecting back-contact solar cells 11, 12, 13, and 14. FIG. 11 only shows a portion of solar module 1100. It is understood that interconnect board 900 may extend to connect all solar cells in the solar module and that solar module 1100 may contain more than 4 solar cells. After lamination, solder joint 1160 electrically connects the bond pads 25 of the solar cells with the corresponding bond pads 950 of the interconnect board. The solder material for solder slug 960 is chosen so that the solder material undergoes reflow soldering at the temperatures used for solar module lamination. Thus, during lamination, solder slug 960 undergoes reflow soldering to create solder joint 1160. Performing reflow soldering during lamination eliminates the need for a separate reflow oven and separate soldering process step saving both time and cost. Interconnect board 900 electrically interconnects the attached solar cells through the conductive traces 1110 in its conductive layer.

Solar cells 11, 12, 13, and 14 are attached to the interconnect board by the thermal interface material. The thermal interface material may be a b-stage material which is only at first partially cured. At the partially cured stage, the thermal interface material is tacky allowing for easy placement of the solar cells onto the interconnect board. After placement of the solar cells, the thermal interface material is fully cured during lamination. The use of interconnect board 900 allows for one process step to perform lamination, adhesive curing, and reflow soldering.

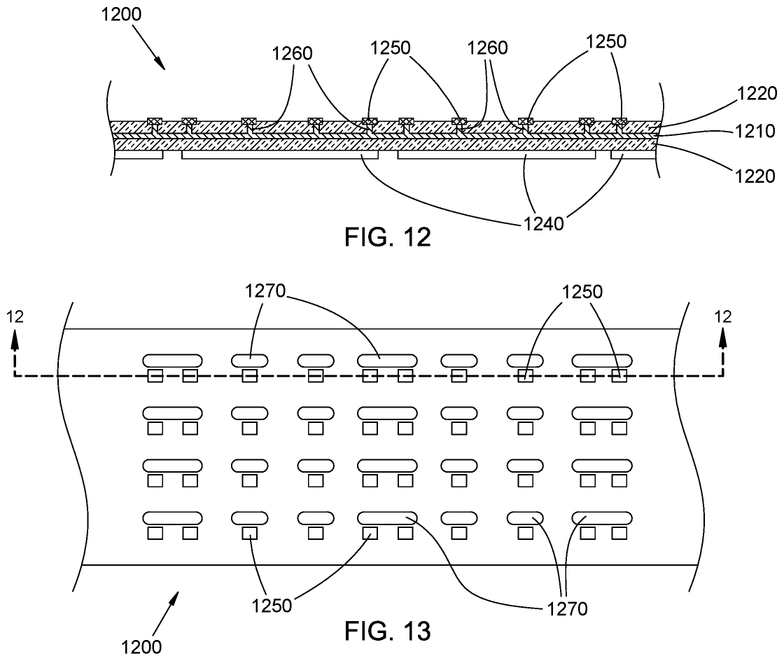

An alternate version of the interconnect board, interconnect board 1200, is shown in FIGS. 12 (cross sectional view) & 13 (plan view). FIG. 12 shows a cross sectional view from line 12-12 in FIG. 13. Interconnect board 1200 comprises a conductive layer 1210 sandwiched between two insulating layers 1220. Conductive layer 1210 may be made from copper and may be etched to form conductive traces. Bond pads 1250 are disposed on one surface of interconnect board 1200 and disposed adjacent to openings 1270. Openings 1270 pass all the way through the interconnect board, e.g. the opening passes through all the insulating layers of the interconnect board. Each opening 1270 has at least one adjacent bond pad. Bond pads 1250 are electrically connected to conductive layer 1210 by electrical path 1260. Electrical path 1260 may be a blind via. Thermal interface material 1240 is disposed on the surface opposite to the surface on which the bond pads are disposed.

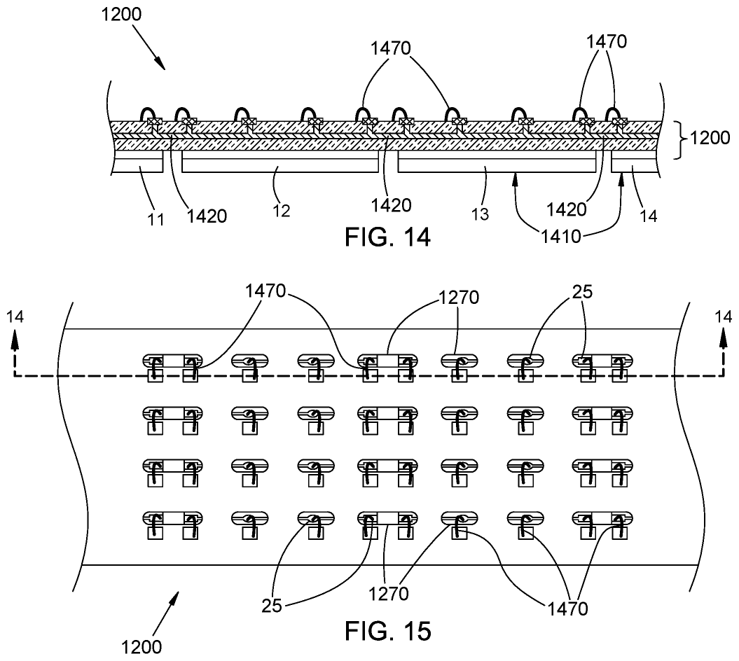

FIG. 15 shows a plan view of interconnect board 1200 with back-contact solar cells 11, 12, 13, and 14 attached. FIG. 14 is a cross-sectional view of the structure in FIG. 15 viewed from line 14-14. The solar cells are placed on the thermal interface material of the interconnect board with the front side 1410 of the solar cells facing away from the interconnect board. That is, in FIG. 14, the front sides of the solar cells are facing down. The solar cells are attached and positioned on the interconnect board so that bond pads 25 on the back side of the solar cells are aligned with openings 1270 of the interconnect board. Alignment of the solar cell bond pads with the openings of the interconnect board provides access to the solar cell's bond pads from the opposite side of the interconnect board on which the solar cells are placed. Wire 1470 is attached to bond pad 1250 of the interconnect board and to solar cell bond pad 25 by ultrasonic wire bonding. Ultrasonic wire bonding forms a wire bond on bond pad 1250 and on bond pad 25. Wire 1470 passes through opening 1270 of the interconnect board. Opening 1270 allows the ultrasonic wire bond head to access and make the wire bond on the bond pads on the back side of the solar cells. The wire bond that attaches wire 1470 to the bond pads may be a ball bond or a wedge bond. One or more wires 1470 may be used to electrically connect a solar cell to the interconnect board. For example, solar cell 13 in FIGS. 14 & 15 is connected to interconnect board 1200 by sixteen wires 1470.

Once the solar cells are attached and wire-bonded to the interconnect board, the conductive traces 1420 in the conductive layer of the interconnect board provide the electrical interconnection between solar cells. More than one conductive trace in the interconnect board may electrically connect adjacent solar cells attached to the interconnect board.

To form a solar module using interconnect board 1200, solar cells are placed on the thermal interface material of the interconnect board. The thermal interface material may be a b-stage material and may be partially cured when the solar cells are placed upon the thermal interface material. Next, the solar cells are electrically connected to interconnect board 1200 using ultrasonic wire bonding. Multiple wire bond heads may be used to increase throughput of the wire bonding step. Next, interconnect board 1200 and the solar cells are encapsulated in an encapsulant in a lamination step to form the solar module.

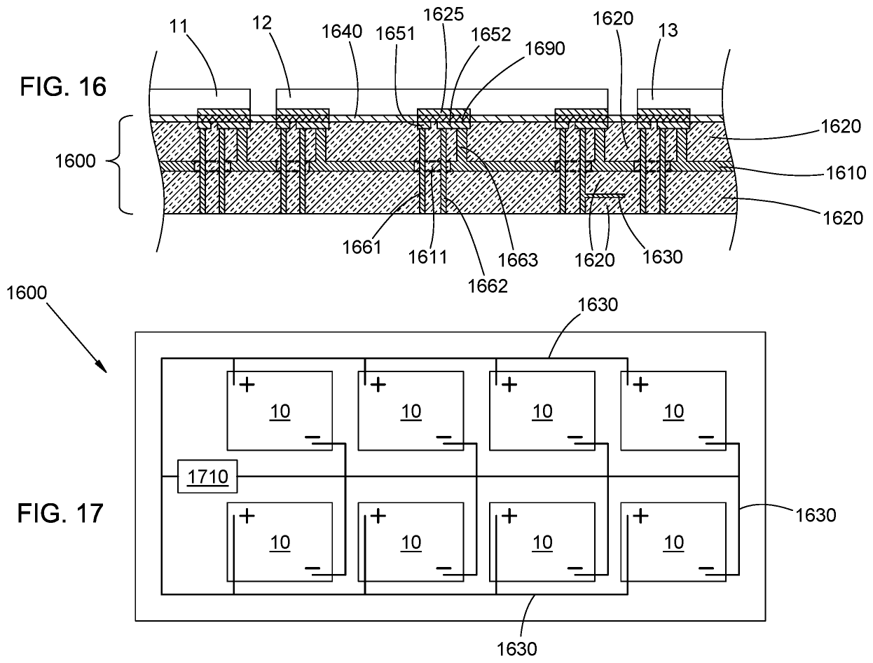

An alternate version of the interconnect board, interconnect board 1600, is shown in FIG. 16. Interconnect board 1600 comprises conductive layers 1610 and 1630 sandwiched between three insulating layers 1620. Conductive layers 1610 and 1630 may be made from copper and each layer may be etched to form conductive traces. Conductive layer 1630 contains conductive traces having higher electrical resistance than the conductive traces formed in conductive layer 1610. The conductive layer 1610 is illustrated in FIG. 16 as having greater thickness than conductive layer 1630 to denote the lower electrical resistance of conductive layer 1610.

Interconnect board 1600 includes two-part bond pads (1651 & 1652) disposed on the surface of the interconnect board. The two-part bond pads are coated with a tin alloy, e.g. solder. An electrical path 1661 connects a first bond pad 1651 of the two-part bond pad to the surface of the interconnect board opposite from the surface on which the bond pads are disposed. Electrical path 1661 may be a through via. Electrical path 1661 does not electrically connect to the conductive traces in conductive layer 1610. For example, the conductive traces in conductive layer 1610 may not be in the same plane as electrical path 1661 as illustrated in FIG. 16 by the dashed line section 1611 in conductive layer 1610. An electrical path 1662 connects a second bond pad 1652 of the two-part bond pad to the surface of the interconnect board opposite from the surface on which the bond pads are disposed. Electrical path 1662 may be a through via. Electrical path 1662 does not electrically connect to the conductive traces in conductive layer 1610. Second bond pad 1652 is also connected to electrical path 1663. Electrical path 1663 connects second bond pad 1652 to the conductive traces in conductive layer 1610. Electrical path 1663 may be a blind via. Conductive traces in conductive layer 1610 and electrical path 1663 have lower electrical resistance than electrical paths 1661 and 1662 and conductive traces in conductive layer 1630.

Disposed on the two-part bond pad is reactive foil 1690. Reactive foil 1690 may be a reactive multilayer foil. Reactive multilayer foils are composed of alternating, thin layers of different reactants that have a propensity to react and generate heat. A variety of two-component reactive multilayers are possible. One such pair of reactants is a reactive multilayer including alternating layers of aluminum and nickel. The reactive multilayer foil can be activated by a small pulse of electrical energy to produce rapid and localized heat. This heat may be produced by a self-sustaining exothermic reaction within the reactive multilayer foil. These exothermic reactions form reaction products that are composed of the two reactants. In the case of an aluminum-nickel multilayer foil, the reaction produces nickel aluminide. Reactive multilayer foils range in thickness between 0.1 to 300 micrometers. For example, reactive foil 1690 may be about 40 micrometers thick or may be about 60 micrometers thick.

Solar cells can be attached to interconnect board 1600 via thermal interface material 1640. FIG. 16 shows back-contact solar cells 11, 12, and 13 attached to interconnect board 1600. The solar cells are electrically connected to the interconnect board through bond pads 1625 of the solar cells which are coated with a tin alloy, e.g. solder. The electrical connection is made by first placing reactive foil 1690 on the interconnect board's solder-coated bond pads. Next, the solar cells are placed on interconnect board 1600 such that the solder-coated bond pads of the solar cells are aligned with a reactive foil on the interconnect board. A compressive force ranging from 0.1 N per square centimeter to 1 N per square centimeter is applied to press together the tin-alloy-coated bond pads of the solar cell and the tin-alloy-coated bond pads of the interconnect board. A voltage is applied across electrical paths 1661 and 1662. For example, a forward bias voltage in the range of 9-12 Volts may be applied across electrical paths 1661 and 1662. The applied voltage supplies the requisite electrical energy needed to activate an exothermic reaction in reactive foil 1690. This exothermic reaction provides the heat necessary to solder the bond pads of the solar cells to the bond pads of the interconnect board. After the reaction, the solder between the bond pads contains the reaction products from the activation of the reactive multilayer foil.

Once the solar cells are attached and electrically connected to interconnect board 1600, interconnect board 1600 provides the electrical connections between solar cells through conductive traces in the conductive layer 1610. FIG. 16 illustrates only a portion of interconnect board 1600. It is understood that interconnect board 1600 may extend to connect more solar cells. In some embodiments, a single interconnect board may be used to connect all the solar cells in a solar module. As such, a single interconnect board may be used to connect multiple solar cells in a string of solar cells in series and connect multiple strings of solar cells together in parallel.

In addition to electrically connecting solar cells to each other, the interconnect board may be used to connect other electronic components to the solar cells. For example, the interconnect board may be used to connect the attached solar cells to a bypass diode. Conductive traces in conductive layer 1630 along with electrical paths 1661 or 1662 or both may be used to connect the solar cells attached to the interconnect board to a bypass diode. FIG. 17 shows a schematic of the conductive traces of conductive layer 1630. The conductive traces in FIG. 17 electrically connect each of the solar cells 10 to a single bypass diode 1710. Although a single bypass diode is illustrated in FIG. 17, it is understood that more than one bypass diode may be used. As shown in FIG. 17, to provide a bypass electrical pathway around a particular solar cell, the bypass diode needs to be connected to at least one positive contact and at least one negative contact on the solar cell.

Typically, a solar module has one bypass diode for a string of solar cells. When a solar cell in the string becomes defective or is unable to properly generate electricity, the bypass diode allows the solar module to bypass the string of cells containing the defective cell allows the cells in the rest of the module to function. When using interconnect board 1600, every solar cell attached to the board is provided with a bypass diode so that if any one cell becomes defective that one cell can be bypassed and all other cells attached to the board can continue to operate. This is significantly better than traditional solar modules where a whole string of cells must be bypassed due to one defective cell in the string.

The conductive traces in layer 1630 have higher resistance than the conductive traces in layer 1610. During normal operation, current flows through the low resistance paths in conductive layer 1610. When a cell becomes inoperative, a high resistance develops in the solar cell which allows the current to flow through the conductive traces in layer 1630 and through the bypass diode. In interconnect board 1600, electrical paths 1661 and 1662 serve a dual purpose. During manufacturing of a solar module, electrical paths 1661 and 1662 are used to apply a voltage to the reactive foil as discussed above. During operation of the solar module, electrical paths 1661 or 1662 form a part of the conductive path between the solar cell and bypass diode 1710.

The second conductive layer to connect the solar cells to a bypass diode may also be incorporated into interconnect boards 900 and 1200. For example, interconnect board 900 may contain a second conductive layer along with electrical paths to connect bond pads 950 to a second conductive layer. Similarly, interconnect board 1200 may contain a second conductive layer along with electrical paths to connect bond pads 1250 to the second conductive layer. In both interconnect boards 900 and 1200, the second conductive layer may have conductive traces similar to that shown in FIG. 17 which electrically connects all the attached solar cells to a bypass diode.

This disclosure is illustrative and not limiting. Further modifications will be apparent to one skilled in the art in light of this disclosure and are intended to fall within the scope of the appended claims. For example, where methods and steps described above indicate certain events occurring in certain order, those of ordinary skill in the art will recognize that the ordering of certain steps may be modified, and that some steps may be omitted or additional steps added, and that such modifications are in accordance with the variations of the invention.

The following enumerated paragraphs (clauses) provide additional non-limiting examples of the disclosure.
1. A string of solar cells comprising: a first and second crystalline silicon solar cell, each crystalline silicon solar cell having a plurality of bond pads; and a plurality of conductive interconnect wires, each interconnect wire electrically connecting the first solar cell to the second solar cell in series, each interconnect wire comprising a first wedge bond bonding the interconnect wire to a bond pad on the first solar cell and a second wedge bond bonding the interconnect wire to a bond pad on the second solar cell.
2. The string of solar cells of claim 1, wherein the first and second crystalline silicone solar cells are back contact solar cells, and wherein the bond pads are disposed on a rear surface of the first and second solar cells.
3. The string of solar cells of claim 1, wherein each interconnect wire comprises a copper core and a tin alloy coating.
4. The string of solar cells of claim 3, wherein each bond pad comprises a tin alloy coating.
5. The string of solar cells of claim 1, wherein each interconnect wire comprises a bend located between the first and second solar cells.
6. The string of solar cells of claim 1, comprising a third crystalline silicon solar cell and wherein each interconnect wire electrically connects the first, second, and third solar cells.
7. The string of solar cells of claim 1, wherein each interconnect wire comprises two or more wedge bonds bonding the interconnect wire to bond pads on the first solar cell and two or more wedge bonds bonding the interconnect wire to bond pads on the second solar cell.
8. The string of solar cells of claim 1, wherein a diameter of each interconnect wire is greater than 200 μm.
9. A method comprising: placing a first and second crystalline silicon solar cells on a fixture; each solar cell having a plurality of bond pads; placing a plurality of conductive interconnect wires on the first and second solar cells; and ultrasonic wire bonding each interconnect wire to a bond pad on the first solar cell and a bond pad on the second solar cell, the ultrasonic wire bonding forming a wedge bond.
10. The method of claim 9, wherein the fixture comprises areas configured to receive solar cells and hump features between the areas.
11. The method of claim 10, comprising before ultrasonic wire bonding, placing clamps on the hump features and heating the clamps.
12. The method of claim 9, wherein each interconnect wire comprises a copper core and a tin alloy coating, and each interconnect wire having a diameter of the interconnect wire is greater than 200 μm.
13. A solar module comprising: an interconnect board comprising:
a conductive layer comprising a conductive trace and bond pads, the conductive layer sandwiched between two insulating layers, a plurality of openings in one of the two insulating layers, each opening aligned with one of the bond pads of the conductive layer, and a plurality of solder joints filling the plurality of openings, each solder joint in contact with one of the bond pads of the conductive layer; and a first and second back-contact solar cells attached to the interconnect board, each solar cell comprising a bond pad disposed on a back surface of the solar cell, the bond pad of each of the solar cell in contact with one of the solder joints of the interconnect board, the conductive trace of the interconnect board electrically connecting the first solar cell to the second solar cell.
14. The solar module of claim 13, comprising a thermal interface material between the interconnect board and the first back-contact solar cell.
15. The solar module of claim 13, wherein each of the insulating layers comprises polyimide and a material selected from the group consisting of FR-4, CEM1, CEM2, CEM3, and CEM4.
16. The solar module of claim 13, wherein the interconnect board comprises a second conductive layer comprising a second conductive trace, the second conductive layer sandwiched between two insulating layers; and an electrical path connecting one of the bond pads of the interconnect board to the second conductive layer.
17. The solar module of claim 16, wherein the interconnect board comprises a bypass diode and the second conductive trace electrically connects the bypass diode to the first solar cell.
18. The solar module of claim 17, wherein the second conductive trace electrically connects the bypass diode to the first and second solar cells.
19. A method of manufacturing a solar module, comprising:
providing an interconnect board comprising: a conductive layer comprising a conductive trace and bond pads, the conductive layer sandwiched between two insulating layers, a plurality of openings in one of the two insulating layers, each opening aligned with one of the bond pads of the conductive layer, and a plurality of solder slugs, each solder slug in contact with one of the bond pads of the conductive layer, each solder slug located within one of the openings;
placing a first and second back-contact solar cells unto to the interconnect board so that bond pads of the first and second solar cells are in contact with the solder slugs; and
laminating the interconnect board and the first and second solar cells in an encapsulant at a temperature sufficient to reflow solder the bond pads of the first and second solar cells to the bond pads of the interconnect board.
20. The method of claim 19, wherein the interconnect board comprises a thermal interface material disposed on a surface of the interconnect board, wherein placing the first and second solar cells comprises placing the first and second solar cells on the thermal interface material, and wherein the temperature during laminating is sufficient to cure the thermal interface material.
21. A solar module comprising: an interconnect board comprising: a first surface and a second surface opposite the first surface, a conductive layer comprising a conductive trace, the conductive layer sandwiched between two insulating layers, a plurality of openings passing through the interconnect board, a plurality of bond pads disposed on the first surface, and a plurality of electrical paths connecting each bond pad to the conductive trace;
a first and second back-contact solar cells attached to the second surface, each solar cell comprising a bond pad disposed on a back surface of the solar cell;
a first wire wire-bonded to the bond pad on the first solar cell and wire-bonded to one of the bond pads of the interconnect board, the first wire passing through one of the openings; and
a second wire wire-bonded to the bond pad on the second solar cell and wire-bonded to another of the bond pads of the interconnect board, the second wire passing through another of the openings, the conductive trace of the interconnect board electrically connecting the first solar cell to the second solar cell.
22. The solar module of claim 21, comprising a thermal interface material between the interconnect board and the first back-contact solar cell.
23. The solar module of claim 21, wherein each of the insulating layers comprises polyimide and a material selected from the group consisting of FR-4, CEM1, CEM2, CEM3, and CEM4.
24. The solar module of claim 21, wherein the interconnect board comprises a second conductive layer comprising a second conductive trace, the second conductive layer sandwiched between two insulating layers; and an electrical path connecting one of the bond pads of the interconnect board to the second conductive layer.
25. The solar module of claim 24, wherein the interconnect board comprises a bypass diode and the second conductive trace electrically connects the bypass diode to the first solar cell.
26. The solar module of claim 25, wherein the second conductive trace electrically connects the bypass diode to the first and second solar cells.
27. A method comprising: providing an interconnect board comprising: a first surface and a second surface opposite the first surface, a conductive layer comprising a conductive trace, the conductive layer sandwiched between two insulating layers, a plurality of openings passing through the interconnect board, a plurality of bond pads disposed on the first surface, and a plurality of electrical paths connecting each bond pad to the conductive trace;
attaching a solar cell onto the second surface, the solar cell comprising a bond pad disposed on a back surface of the solar cell; and
wire bonding a wire to the bond pad of the solar cell and to one of the bond pads of the interconnect board where the wire passes through one of the openings.
28. The method of claim 27, comprising attaching a second solar cell onto the second surface of the interconnect board, the second solar cell comprising a bond pad disposed on a back surface of the second solar cell; and wire bonding a second wire to the bond pad of the second solar cell and to another of the bond pads of the interconnect board where the second wire passes through another one of the openings.
29. An interconnect board comprising: a first surface and a second surface opposite the first surface; a conductive layer comprising a conductive trace, the conductive layer sandwiched between two insulating layers; a plurality of bond pads disposed on the first surface, each bond pad comprising a first part, a second part, and a solder coating; a plurality of electrical paths connecting each bond pad to the conductive trace; and a plurality of reactive multilayer foils, each reactive multilayer foil disposed on one of the bond pads so that the reactive multilayer foil is in contact with both the first and second parts of the bond pad.
30. The interconnect board of claim 29, comprising: a first electrical path contacting the first part of a bond pad and extending through the interconnect board to the second surface; and a second electrical path contacting the second part of the bond pad and extending through the interconnect board to the second surface.
31. The interconnect board of claim 29, wherein each of the insulating layers comprises polyimide and a material selected from the group consisting of FR-4, CEM1, CEM2, CEM3, and CEM4.
32. The interconnect board of claim 29, comprising a second conductive layer comprising a second conductive trace, the second conductive layer sandwiched between two insulating layers; and an electrical path connecting one of the bond pads of the interconnect board to the second conductive layer.
33. The interconnect board of claim 32, comprising a bypass diode and wherein the second conductive trace electrically connects the bypass diode to the one bond pad.
34. The interconnect board of claim 29, wherein the reactive multilayer foils comprise alternating layers of aluminum and nickel.
35. The interconnect board of claim 34, wherein the reactive multilayer foils have a thickness of less than 300 micrometers.
36. A method comprising: providing an interconnect board comprising: a conductive layer comprising a conductive trace, the conductive layer sandwiched between two insulating layers, a bond pad disposed on a first surface of the interconnect board, the bond pad comprising a first part, a second part, and a solder coating, an electrical path connecting the bond pad to the conductive trace, and a reactive multilayer foil disposed on the bond pad, the reactive multilayer foil in contact with both the first and second parts the bond pad;
placing a solar cell on the interconnect board so that a bond pad of the solar cell is in contact with the reactive multilayer foil; and
applying a voltage across the first and second parts of the bond pad to activate the reactive multilayer foil to solder the bond pad of the solar cell to the bond pad of the interconnect board.
37. A solar module comprising: an interconnect board comprising: a conductive layer comprising a conductive trace, the conductive layer sandwiched between two insulating layers, a plurality of bond pads disposed on a surface of the interconnect board, and a plurality of electrical paths electrically connecting each bond pad to the conductive trace; and a first and second back-contact solar cells attached to the interconnect board, each solar cell comprising a bond pad disposed on a back surface of the solar cell, the bond pad of each of the solar cell attached to one of the bond pads of the interconnect board by solder, the solder comprising a reaction product from the activation of a reactive multilayer foil, the conductive trace of the interconnect board electrically connecting the first solar cell to the second solar cell.
38. The solar module of claim 37, wherein the interconnect board comprises a second conductive layer comprising a second conductive trace, the second conductive layer sandwiched between two insulating layers; and an electrical path connecting one of the bond pads of the interconnect board to the second conductive layer.
39. The solar module of claim 38, wherein the interconnect board comprises a bypass diode and the second conductive trace electrically connects the bypass diode to the first solar cell.
40. The solar module of claim 39, wherein the second conductive trace electrically connects the bypass diode to the first and second solar cells.
41. The solar module of claim 37, comprising a thermal interface material between the interconnect board and the first back-contact solar cell.
42. The solar module of claim 37, wherein each of the insulating layers comprises polyimide and FR-4.
43. The solar module of claim 37, wherein the reaction product is nickel aluminide.

What is claimed is:

1. A string of solar cells comprising:
a first and second crystalline silicon solar cell, each crystalline silicon solar cell having a plurality of bond pads; and
a plurality of conductive interconnect wires, each interconnect wire electrically connecting the first solar cell to the second solar cell in series, each interconnect wire comprising a first wedge bond bonding the interconnect wire to a bond pad on the first solar cell and a second wedge bond bonding the interconnect wire to a bond pad on the second solar cell.

2. The string of solar cells of claim 1, wherein the first and second crystalline silicone solar cells are back contact solar cells, and wherein the bond pads are disposed on a rear surface of the first and second solar cells.

3. The string of solar cells of claim 1, wherein each interconnect wire comprises a copper core and a tin alloy coating.

4. The string of solar cells of claim 3, wherein each bond pad comprises a tin alloy coating.

5. The string of solar cells of claim 1, wherein each interconnect wire comprises a bend located between the first and second solar cells.

6. The string of solar cells of claim 1, comprising a third crystalline silicon solar cell and wherein each interconnect wire electrically connects the first, second, and third solar cells.

7. The string of solar cells of claim 1, wherein each interconnect wire comprises two or more wedge bonds bonding the interconnect wire to bond pads on the first solar cell and two or more wedge bonds bonding the interconnect wire to bond pads on the second solar cell.

8. The string of solar cells of claim 1, wherein a diameter of each interconnect wire is greater than 200 μm.

9. A method comprising:
placing a first and second crystalline silicon solar cells on a fixture; each solar cell having a plurality of bond pads;
placing a plurality of conductive interconnect wires on the first and second solar cells; and
ultrasonic wire bonding each interconnect wire to a bond pad on the first solar cell and a bond pad on the second solar cell, the ultrasonic wire bonding forming a wedge bond.

10. The method of claim 9, wherein the fixture comprises areas configured to receive solar cells and hump features between the areas.

11. The method of claim 10, comprising before ultrasonic wire bonding, placing clamps on the hump features and heating the clamps.

12. The method of claim 9, wherein each interconnect wire comprises a copper core and a tin alloy coating, and each interconnect wire having a diameter of the interconnect wire is greater than 200 μm.

13. A solar module comprising:
an interconnect board comprising:
a conductive layer comprising a conductive trace and bond pads, the conductive layer sandwiched between two insulating layers,
a plurality of openings in one of the two insulating layers, each opening aligned with one of the bond pads of the conductive layer, and
a plurality of solder joints filling the plurality of openings, each solder joint in contact with one of the bond pads of the conductive layer; and
a first and second back-contact solar cells attached to the interconnect board, each solar cell comprising a bond pad disposed on a back surface of the solar cell, the bond pad of each of the solar cell in contact with one of the solder joints of the interconnect board,
the conductive trace of the interconnect board electrically connecting the first solar cell to the second solar cell.

14. The solar module of claim 13, comprising a thermal interface material between the interconnect board and the first back-contact solar cell.

15. The solar module of claim 13, wherein each of the insulating layers comprises polyimide and a material selected from the group consisting of FR-4, CEM1, CEM2, CEM3, and CEM4.

16. The solar module of claim 13, wherein the interconnect board comprises
a second conductive layer comprising a second conductive trace, the second conductive layer sandwiched between two insulating layers; and
an electrical path connecting one of the bond pads of the interconnect board to the second conductive layer.

17. The solar module of claim 16, wherein the interconnect board comprises a bypass diode and the second conductive trace electrically connects the bypass diode to the first solar cell.

18. The solar module of claim 17, wherein the second conductive trace electrically connects the bypass diode to the first and second solar cells.

19. A method of manufacturing a solar module, comprising:
providing an interconnect board comprising:
a conductive layer comprising a conductive trace and bond pads, the conductive layer sandwiched between two insulating layers,
a plurality of openings in one of the two insulating layers, each opening aligned with one of the bond pads of the conductive layer, and
a plurality of solder slugs, each solder slug in contact with one of the bond pads of the conductive layer, each solder slug located within one of the openings;
placing a first and second back-contact solar cells unto to the interconnect board so that bond pads of the first and second solar cells are in contact with the solder slugs; and
laminating the interconnect board and the first and second solar cells in an encapsulant at a temperature sufficient to reflow solder the bond pads of the first and second solar cells to the bond pads of the interconnect board.

20. The method of claim 19, wherein the interconnect board comprises a thermal interface material disposed on a surface of the interconnect board, wherein placing the first and second solar cells comprises placing the first and second solar cells on the thermal interface material, and wherein the temperature during laminating is sufficient to cure the thermal interface material.
